(19) United States
(12) Patent Application Publication
(10) Pub. No.: US 2026/0169028 A1
(43) Pub. Date: Jun. 18, 2026

(54) AUTOMATED CHIP TESTING DEVICE AND AUTOMATED CHIP TESTING METHOD

(71) Applicant: Hosin Global Electronics Co., LTD, Shenzhen (CN)

(72) Inventors: Siu Tung LAM, Shenzhen (CN); Xuelou HUANG, Shenzhen (CN); ChunRong Liu, Shenzhen (CN); Sihua Chen, Shenzhen (CN)

(73) Assignee: Hosin Global Electronics Co., LTD, Shenzhen (CN)

(21) Appl. No.: 19/387,455

(22) Filed: Nov. 12, 2025

(30) Foreign Application Priority Data
Dec. 17, 2024 (CN) 202411861638.4

(51) Int. Cl. G01R 1/04; G01R 1/067; G01R 31/26

(52) U.S. Cl. CPC G01R 1/0433; G01R 1/06766; G01R 1/06794; G01R 31/2601

(57) ABSTRACT

An automated chip testing device includes a main body, a processor, at least one test socket placed with a chip to be tested, a pressing device including a pressing rod and at least one protruding portion disposed on the pressing rod, and at least one sensing device. The processor receives a test instruction and generates and outputs a test signal according to the test instruction. The pressing device and the sensing device receive the test signal. The pressing device moves toward the test socket based on the test signal and presses the chip to be tested through the protruding portion. The sensing device determines whether a distance between the sensing device and an object to be sensed satisfies a predetermined condition based on the test signal. If yes, the processor starts a test program and outputs test data to the test socket. An automated chip testing method is also provided.

### CROSS-REFERENCE TO RELATED APPLICATION

This application claims the priority benefit of China application serial no. 202411861638.4, filed on December 17, 2024. The entirety of the above-mentioned patent application is hereby incorporated by reference herein and made a part of this specification.

### BACKGROUND

### TECHNICAL FIELD

The disclosure relates to a testing device, and particularly relates to an automated chip testing device and an automated chip testing method.

### DESCRIPTION OF RELATED ART

At present, in the field of automated chip testing, generally, a robotic arm first picks up a chip from a tray and then places it in a test socket. Next, a pressing device applies pressure to the chip to ensure good contact between the chip and the test socket. Finally, the test socket executes a test program on the chip.

In the above process, the test program is generally initiated by a timer. Specifically, after the chip is positioned in the test socket, the timer may instruct the test socket to execute the test program after a fixed delay.

However, conditions such as increased usage time, component wear and aging, and external environment changes may all reduce the accuracy of the timer, causing the test program to be initiated at incorrect time points. The testing efficiency and correctness of the chip is thus affected.

### SUMMARY

In view of the above, the disclosure provides an automated chip testing device and an automated chip testing method capable of effectively improving the testing efficiency and correctness of a chip.

The disclosure provides an automated chip testing device including a main body, a processor, at least one test socket, a pressing device, and at least one sensing device. The at least one test socket, the pressing device, and the at least one sensing device are located on the main body and are coupled to the processor. The pressing device includes a pressing rod and at least one protruding portion disposed on the pressing rod. The test socket is placed with a chip to be tested. The processor receives a test instruction and generates and outputs a test signal according to the test instruction. The pressing device and the sensing device receive the test signal. The pressing device moves toward the test socket based on the test signal and presses the chip to be tested in the test socket through the at least one protruding portion. The sensing device determines whether a distance between the sensing device and an object to be sensed satisfies a predetermined condition based on the test signal. If yes, the processor starts a test program and outputs test data to the at least one test socket.

In an embodiment of the disclosure, the sensing device is located on a first surface of the main body, and the first surface is a surface facing the pressing device.

In an embodiment of the disclosure, the sensing device is located on the pressing device.

In an embodiment of the disclosure, the protruding portion further includes a first protruding portion and a second protruding portion. The sensing device is located between the first protruding portion and the second protruding portion. The first protruding portion and the second protruding portion are higher than the sensing device.

In an embodiment of the disclosure, the sensing device further includes a first sensing device and a second sensing device. The first sensing device is configured to emit a detection signal to a surface of the chip to be tested in the test socket. The second sensing device is configured to receive the detection signal reflected from the surface of the chip to be tested. If the second sensing device does not receive the detection signal within a predetermined range, the second sensing device transmits an alarm signal to the processor. The processor transmits a stop signal to the pressing device based on the alarm signal and outputs an alarm notification.

In an embodiment of the disclosure, after the pressing device moves toward the test socket by a predetermined distance, the sensing device is further configured to detect a pressing distance and determine whether the pressing distance is within a predetermined distance range. If not within the predetermined distance range, the processor outputs a compensation signal to the pressing device, and the pressing device adjusts a pressing-down distance according to the compensation signal.

In an embodiment of the disclosure, the pressing distance is a distance between the pressing rod and the first surface or the chip to be tested.

In an embodiment of the disclosure, the sensing device further includes a third sensing device and a fourth sensing device. The third sensing device is configured to detect a first distance. The fourth sensing device is configured to detect a second distance. The processor is further configured to determine whether a predetermined threshold is exceeded according to the first distance and the second distance. If yes, the processor transmits a stop signal to the pressing device and outputs an abnormality notification.

In an embodiment of the disclosure, the first distance is a distance between the third sensing device and the first surface, and the second distance is a distance between the fourth sensing device and the pressing rod.

The disclosure further provides an automated chip testing method, and the method includes the following steps. A processor receives a test instruction and generates and outputs a test signal according to the test instruction. A pressing device and a sensing device receive the test signal. The pressing device moves toward a test socket based on the test signal and presses a chip to be tested in the test socket through at least one protruding portion in the pressing device. The sensing device determines whether a distance between the sensing device and an object to be sensed satisfies a predetermined condition based on the test signal. If yes, the processor starts a test program and outputs test data to the test socket.

To sum up, in the automated chip testing device and automated chip testing method provided by the disclosure, testing efficiency and testing correctness are improved, and the chips to be tested are prevented from being damaged.

To make the aforementioned more comprehensible, several embodiments accompanied with drawings are described in detail as follows.

### BRIEF DESCRIPTION OF THE DRAWINGS

FIG. 1 is a schematic view of an automated chip testing device according to an embodiment of the disclosure.

FIG. 2 is a schematic view of test sockets, chips to be tested, a main body, a pressing device, and sensing devices according to a first embodiment of the disclosure.

FIG. 3 is a schematic view of management of a test program according to the first embodiment of the disclosure.

FIG. 4 is a schematic view of management of the test program according to the first embodiment of the disclosure.

FIG. 5 is a schematic view of management of a self-detection mechanism according to the first embodiment of the disclosure.

FIG. 6 is a schematic view of management of over-pressing and non-pressing issues according to the first embodiment of the disclosure.

FIG. 7 is a schematic view of management of a warpage issue according to the first embodiment of the disclosure.

FIG. 8 is a schematic view of test sockets, the chips to be tested, the main body, a pressing device, and sensing devices according to a second embodiment of the disclosure.

FIG. 9 is a schematic view of test sockets, the chips to be tested, the main body, a pressing device, and sensing devices according to a third embodiment of the disclosure.

FIG. 10 is a schematic view of test sockets, the chips to be tested, the main body, a pressing device, and sensing devices according to a fourth embodiment of the disclosure.

FIG. 11 is a flow chart of an automated chip testing method according to an embodiment of the disclosure.

### DESCRIPTION OF THE EMBODIMENTS

Descriptions of the disclosure are given with reference to the exemplary embodiments illustrated by the accompanying drawings. Wherever possible, the same reference numbers are used in the drawings and the description to refer to the same or like parts.

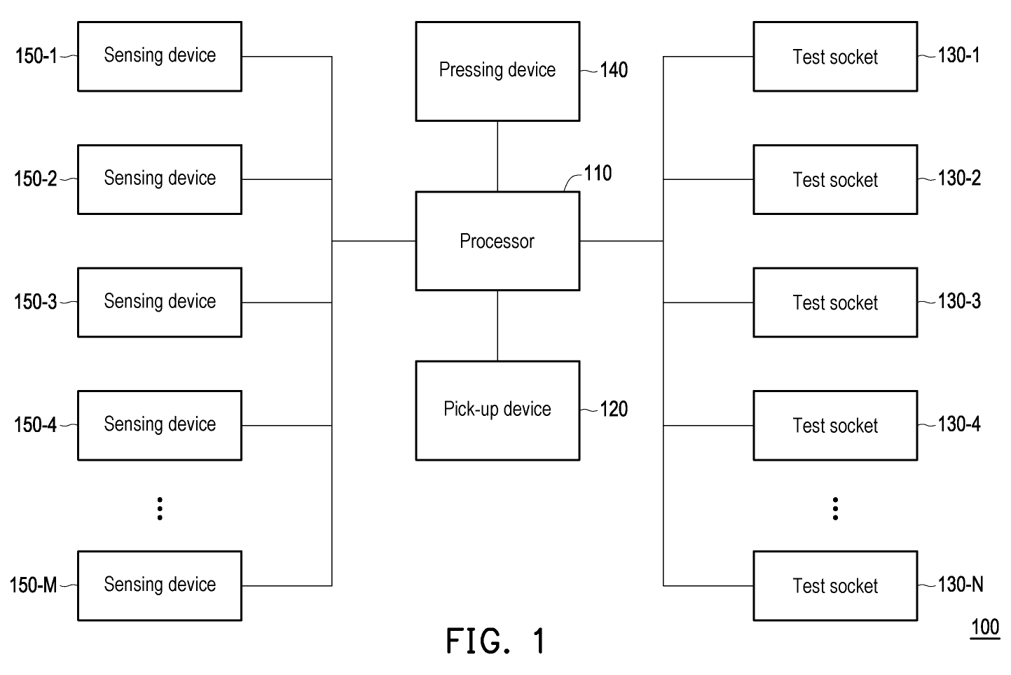

FIG. 1 is a schematic view of an automated chip testing device according to an embodiment of the disclosure. With reference to FIG. 1, an automated chip testing device 100 includes a processor 110, a pick-up device 120, test sockets 130-1 to 130-N, a pressing device 140, and sensing devices 150-1 to 150-M. The processor 110 is coupled to the pick-up device 120, the test sockets 130-1 to 130-N, the pressing device 140, and the sensing devices 150-1 to 150-M. The sensing devices 150-1 to 150-M may be, for example, non-contact sensing devices, infrared sensing devices, or laser sensing devices. The number of the test sockets 130-1 to 130-N and the number of the sensing devices 150-1 to 150-M may be designed according to actual needs and are not limited in the disclosure. Further, the number of the test sockets 130-1 to 130-N may be equal to the number of the sensing devices 150-1 to 150-M, or the number of the test sockets 130-1 to 130-N may be different from the number of the sensing devices 150-1 to 150-M, which are not limited in the disclosure.

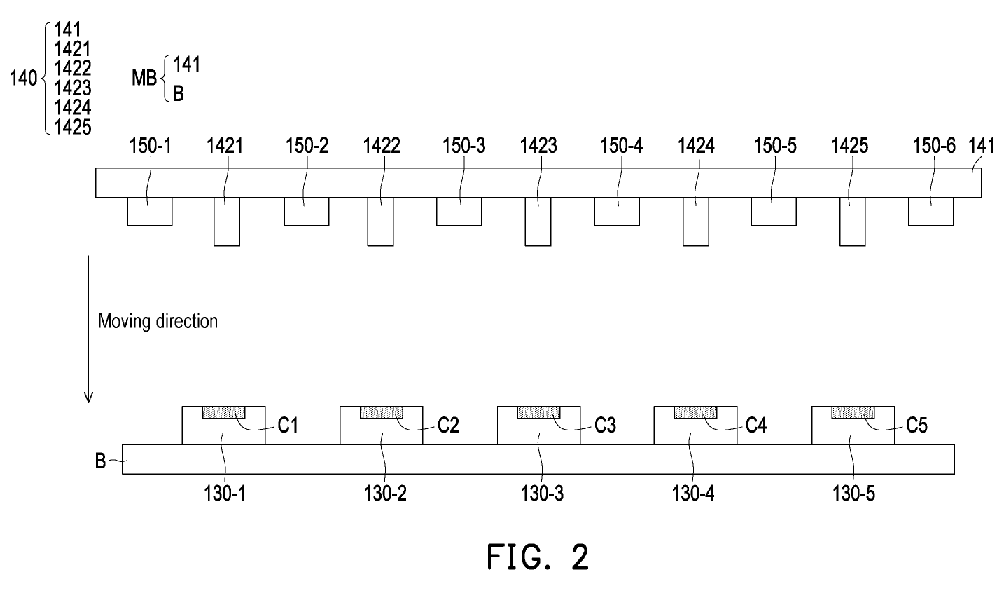

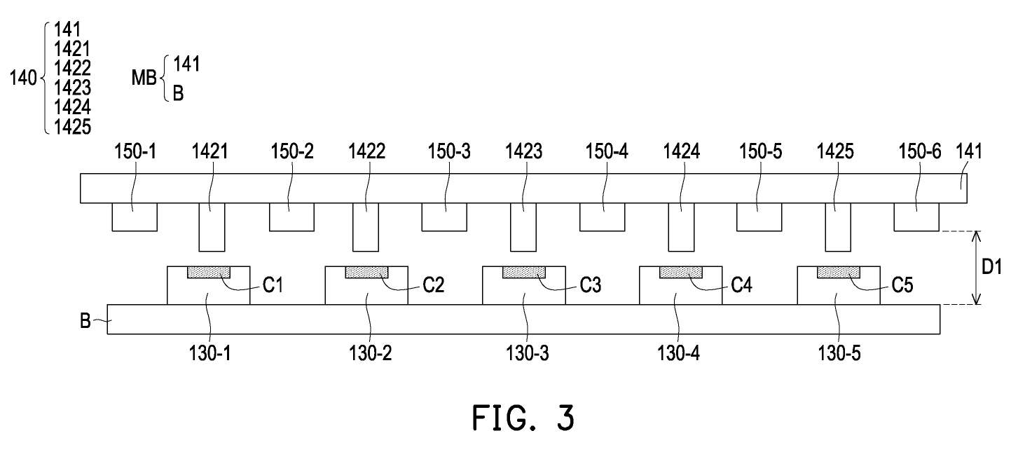

FIG. 2 is a schematic view of test sockets, chips to be tested, a main body, a pressing device, and sensing devices according to a first embodiment of the disclosure. FIG. 3 is a schematic view of management of a test program according to the first embodiment of the disclosure. With reference to FIG. 2 and FIG. 3, in this embodiment, the number of the test sockets 130-1 to 130-5 is 5, and the number of the sensing devices 150-1 to 150-6 is 6. The pressing device 140 includes a pressing rod 141 and protruding portions 1421 to 1425 disposed on the pressing rod 141. The test sockets 130-1 to 130-5, the pressing device 140, and the sensing devices 150-1 to 150-6 are located on a main body MB. The main body MB includes a machine main body B and the pressing rod 141 of the pressing device 140. In this embodiment, the test sockets 130-1 to 130-5 are spaced apart from each other and disposed on the machine main body B. The sensing devices 150-1 to 150-6 are located on the pressing device 140. For instance, the sensing devices 150-2 to 150-5 in FIG. 2 are disposed between the protruding portions 1421 to 1425, and the sensing devices 150-1 to 150-6 are disposed on both sides of the pressing rod 141. In this embodiment, a height of the sensing devices 150-1 to 150-6 needs to be lower than heights of the protruding portions 1421 to 1425 and the test sockets 130-1 to 130-5, so that the pressing of the chips to be tested C1 to C5 by the pressing device 140 can be prevented from being affected.

When a test procedure is to be executed on the chips to be tested, test personnel may transmit a test instruction to the automated chip testing device 100 through, for example, a host computer (not shown). The processor 110 may receive the test instruction, generate a test signal according to the test instruction, and output the test signal to the pick-up device 120, the pressing device 140, the sensing devices 150-1 to 150-6, and/or the test sockets 130-1 to 130-5.

The pick-up device 120 may place the chips to be tested C1 to C5 respectively on the test sockets 130-1 to 130-5 based on the test signal. For instance, a material preparation station (not shown) is provided beside the automated chip testing device 100. The material preparation station is configured to be placed with a material tray (not shown), and the material tray is configured to be place with the chips to be tested C1 to C5.

Next, the pressing device 140 may move toward the test sockets 130-1 to 130-5 based on the test signal and press the chips to be tested C1 to C5 in the test sockets 130-1 to 130-5 through the protruding portions 1421 to 1425. As shown in FIG. 2, the pressing device 140 may move toward the test sockets 130-1 to 130-5 in a moving direction (for example, vertically downward).

In order to effectively improve testing efficiency and accuracy of chips, the sensing devices 150-1 to 150-6 may determine whether a distance between the sensing devices 150-1 to 150-6 and an object to be sensed satisfies a predetermined condition based on the test signal. In this embodiment, the sensing devices 150-1 to 150-6 may, for example, continuously detect the distance between the sensing devices 150-1 to 150-6 and the chips to be tested C1 to C5 (objects to be sensed). That is, the sensing devices 150-1 to 150-6 may continuously detect the descending condition of the pressing device 140, which means the actual condition of the pressing device 140 pressing the chips to be tested C1 to C5. In another embodiment, the sensing devices 150-1 to 150-6 may, for example, continuously detect the distance between the sensing devices 150-1 to 150-6 and the pressing rod 141 (object to be sensed). In another embodiment, the sensing devices 150-1 to 150-6 may, for example, continuously detect the distance between the sensing devices 150-1 to 150-6 and the machine main body B (object to be sensed), and the disclosure is not limited thereto.

When the distance detected by the sensing devices 150-1 to 150-6 is not a distance D1 as shown in FIG. 3, the sensing devices 150-1 to 150-6 may continue to detect the distance between themselves and the machine main body B until the detected distance is the distance D1. Subsequently, when the distance detected by the sensing devices 150-1 to 150-6 is the distance D1, the sensing devices 150-1 to 150-6 may determine that the distance between the sensing devices 150-1 to 150-6 and the object to be sensed (for example, the machine main body B) satisfies the predetermined condition. Simply put, the distance D1 in FIG. 3 is the distance between the sensing devices 150-1 to 150-6 and the machine main body B. Therefore, after the pressing device 140 starts to move toward the test sockets 130-1 to 130-5, the sensing devices 150-1 to 150-6 may continuously detect the distance between themselves and the machine main body B until this distance is the distance D1 (that is, satisfying the predetermined condition).

Accordingly, the sensing devices 150-1 to 150-6 may instruct the processor 110 to start a test program and output test data to the test sockets 130-1 to 130-5. The test sockets 130-1 to 130-5 may respectively execute the test program on the chips to be tested C1 to C5 according to the test data. It is worth mentioning that in conventional practices, after the processor 110 receives the test instruction, the processor 110 starts the test program after a fixed delay. However, problems such as increased usage time and component wear and aging may cause the test program to be started at incorrect time points, so that the testing efficiency and accuracy of chips is affected. The automated chip testing device 100 of the disclosure may detect the actual condition of the pressing device 140 pressing the chips to be tested C1 to C5 through the sensing devices 150-1 to 150-6 and accordingly instruct the processor 110 to start the test program at the most appropriate timing (that is, when the predetermined condition is satisfied), so the testing efficiency and accuracy may thus be effectively improved.

It should be noted that if the sensing devices 150-1 to 150-6 do not detect that the distance between themselves and the machine main body B is D1 within predetermined time, the sensing devices 150-1 to 150-6 may output an alarm signal to the processor 110. The processor 110 may then output an alarm notification based on the alarm signal to instruct the test personnel to perform maintenance on the automated chip testing device 100. Specifically, if the sensing devices 150-1 to 150-6 do not detect that the distance between themselves and the machine main body B is D1 within the predetermined time, it indicates that the descending condition of the pressing device 140 is erroneous and/or the detection condition of the sensing devices 150-1 to 150-6 is erroneous. Therefore, the processor 110 may instruct the pressing device 140 to stop moving to temporarily not start the test program and output an alarm notification, so as to instruct the test personnel to perform maintenance on the automated chip testing device 100.

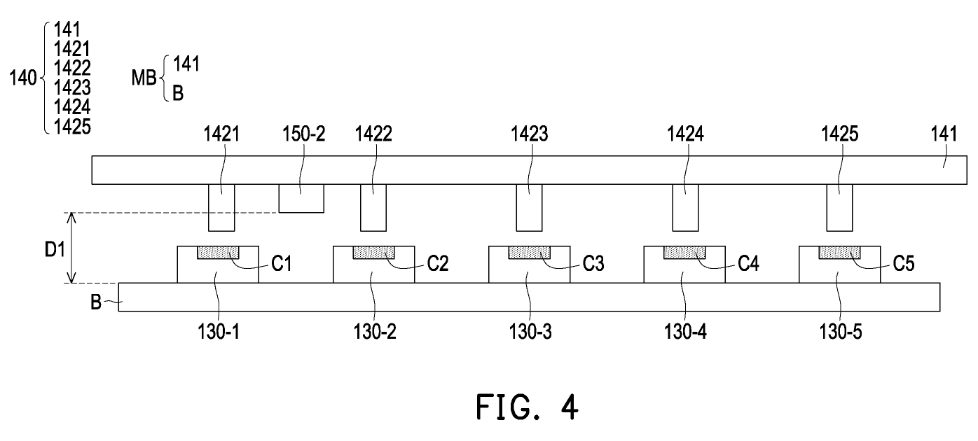

In an embodiment, only one sensing device (e.g., the sensing device 150-2) may be used to detect the actual condition of the pressing device 140 pressing the chips to be tested C1 to C5. FIG. 4 is a schematic view of management of a test program according to the first embodiment of the disclosure. With reference to FIG. 4, in this embodiment, only one sensing device 150-2 is provided to detect the timing for starting the test program. Specifically, the sensing device 150-2 receives a test signal from the processor 110 and determines whether the distance between the sensing device 150-2 and an object to be sensed satisfies the predetermined condition based on the test signal. For instance, the sensing device 150-2 may continuously detect the distance to the object to be sensed based on the test signal until the detected distance is the distance D1 (that is, the predetermined condition is satisfied). If the detected distance is the distance D1, the sensing device 150-1 may instruct the processor 110 to start the test program and output test data to the test sockets 130-1 to 130-5, so that the processor 110 may start the test program at the most appropriate timing, and the testing efficiency and accuracy may thus be effectively improved.

It is worth mentioning that since the automated chip testing device 100 of the disclosure instructs to start the test program through the sensing devices 150-1 to 150-6, how to ensure the accuracy of the sensing devices 150-1 to 150-6 is an important issue. In this regard, in the disclosure, a self-detection mechanism is provided for the sensing devices 150-1 to 150-6. Specifically, before the distance to the object to be sensed is detected, any number of the sensing devices 150-1 to 150-6 may detect a first distance and a second distance and transmit the detected first distance and second distance to the processor 110. Accordingly, the processor 110 may determine whether a predetermined threshold is exceeded according to the first distance and the second distance. If the predetermined threshold is not exceeded, the processor 110 may determine that the sensing devices 150-1 to 150-6 may continue to detect the distance between themselves and the object to be sensed. Conversely, if the predetermined threshold is exceeded, the processor 110 may transmit a stop signal to the pressing device 140 to instruct the pressing device 140 to stop moving. In addition, the processor 110 may also output an abnormality notification, so as to instruct the test personnel to perform maintenance on the sensing devices 150-1 to 150-6. Accordingly, the self-detection mechanism provided by the disclosure may ensure the accuracy of the sensing devices 150-1 to 150-6, and the correctness of testing is thus effectively improved.

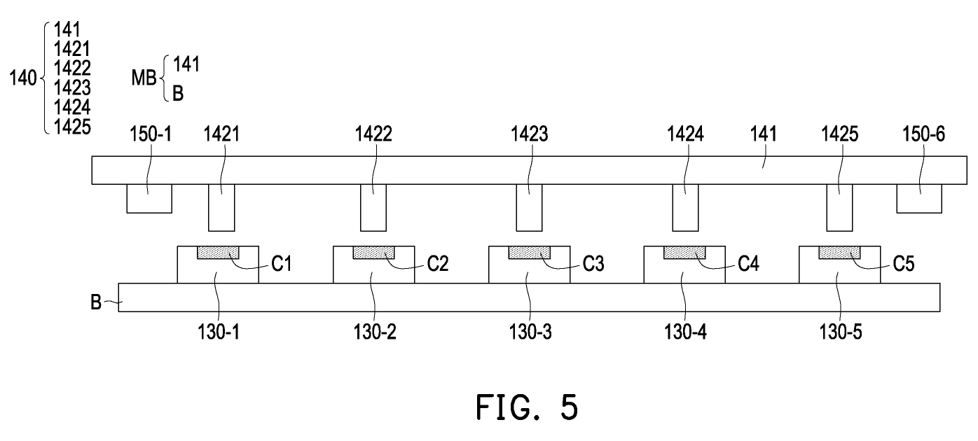

Specifically, referring to FIG. 5, FIG. 5 is a schematic view of management of a self-detection mechanism according to the first embodiment of the disclosure. In this embodiment, before the distance to the object to be sensed is detected, the sensing device 150-1 (also referred to as a third sensing device) and the sensing device 150-6 (also referred to as a fourth sensing device) may respectively detect the first distance and the second distance. It should be noted that both the sensing device 150-1 and the sensing device 150-6 are disposed on the pressing device 140 (i.e., on the pressing rod 141). Therefore, the first distance may be, for example, the distance between the sensing device 150-1 and the machine main body B, and the second distance may be, for example, the distance between the sensing device 150-6 and the machine main body B. The sensing device 150-1 and the sensing device 150-6 may respectively transmit the measured first distance and second distance to the processor 110. The processor 110 may determine whether the predetermined threshold is exceeded according to the first distance and the second distance. For instance, the processor 110 may calculate an error value between the first distance and the second distance and determine whether this error value exceeds the predetermined threshold. If the predetermined threshold is not exceeded, the processor 110 may determine that the sensing devices 150-1 to 150-6 may continue to detect the distance between themselves and the object to be sensed. Conversely, if the predetermined threshold is exceeded, the processor 110 may output a stop signal to instruct the pressing device 140 to stop moving and output an abnormality notification to instruct the test personnel to perform maintenance, so as to improve the correctness of testing.

It is worth mentioning that the sensing device 150-1 and the sensing device 150-6 in FIG. 5 are disposed on the same component (i.e., the pressing device 140). In another embodiment, the third sensing device and the fourth sensing device may also be disposed on different components. For instance, the third sensing device is disposed on the pressing device 140, and the fourth sensing device is disposed on the machine main body B. The embodiment where the third sensing device and the fourth sensing device may also be disposed on different components are to be described in the following paragraphs.

On the other hand, as the usage time increases, the pressing device 140 is subject to wear, so its movement accuracy is affected. That is, during the process of the pressing device 140 moving toward the test sockets 130-1 to 130-5, the moving distance of the pressing device 140 may be erroneous, so that problems of the pressing device 140 over-pressing the chips to be tested C1 to C5 or the pressing device 140 failing to press the chips to be tested C1 to C5 may occur.

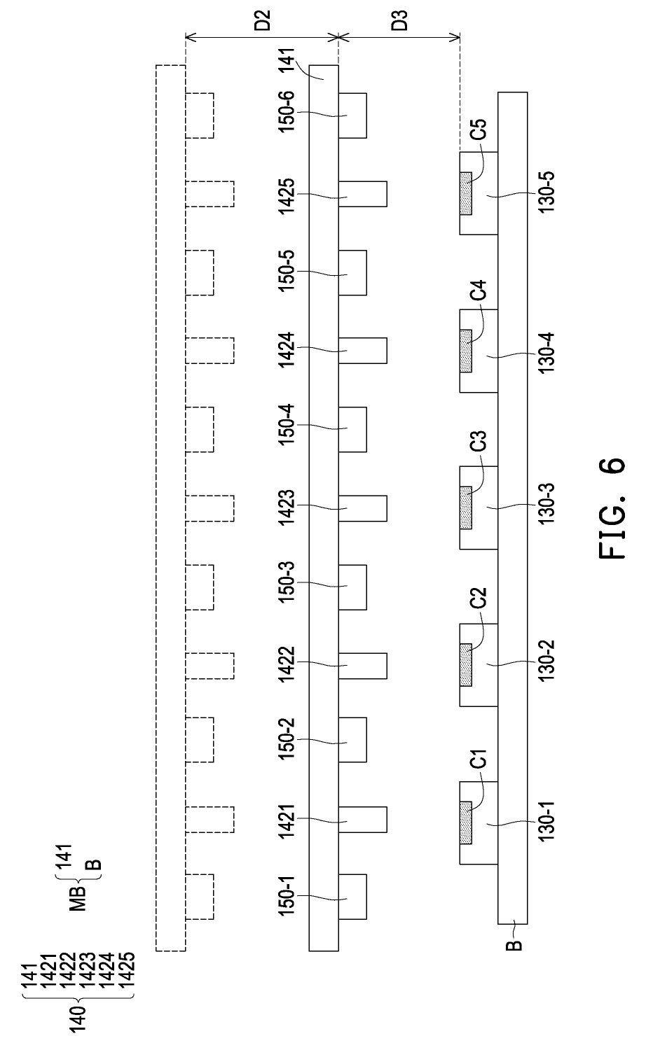

In this regard, in the embodiments of the disclosure, an effective improvement solution is provided. FIG. 6 is a schematic view of management of over-pressing and non-pressing issues according to the first embodiment of the disclosure.

With reference to FIG. 6, in this embodiment, after the pressing device 140 moves toward the test sockets 130-1 to 130-5 by a distance D2 (also referred to as a predetermined distance) based on the test signal, the sensing device 150-6 (or any one of the sensing devices 150-1 to 150-6) may detect a pressing distance and determine whether the pressing distance is within a predetermined distance range. Assuming under ideal conditions, after the pressing device 140 moves toward the test sockets 130-1 to 130-5 by the distance D2, the distance between a lower surface of the pressing rod 141 and the chips to be tested C1 to C5 should be a distance D3. In this embodiment, after the pressing device 140 moves toward the test sockets 130-1 to 130-5 by the predetermined distance D2, the pressing device 140 may pause movement. Subsequently, the sensing device 150-6 may detect whether a distance between the lower surface of the pressing rod 141 and the chip to be tested C5 (i.e., the pressing distance) is within the predetermined range. The predetermined range is associated with the distance D3. For instance, the predetermined range may be, for example, a range within plus or minus 0.1 cm of the distance D3. In an exemplary embodiment, the pressing distance may also be, for example, a distance between the pressing rod 141 and a surface (also referred to as a first surface) on the main body MB facing the pressing device 140.

If the pressing distance is within the predetermined range, the pressing device 140 may continue to move toward the test sockets 130-1 to 130-5 to press the chips to be tested C1 to C5. Specifically, if the pressing distance is within the predetermined range, it indicates that the pressing accuracy of the pressing device 140 has no problem, and the pressing device 140 may not subsequently cause over-pressing and non-pressing problems of the chips to be tested C1 to C5, so the pressing device 140 may continue to approach the test sockets 130-1 to 130-5 to press the chips to be tested C1 to C5.

Conversely, if the pressing distance is not within the predetermined range, the sensing device 150-6 may instruct the processor 110 to output a compensation signal to the pressing device 140, and the pressing device 140 may adjust the pressing distance according to the compensation signal. Specifically, if the pressing distance is not within the predetermined range, it indicates that the movement accuracy of the pressing device 140 has a problem, which may subsequently cause over-pressing or non-pressing problems of the chips to be tested C1 to C5. Accordingly, if the pressing distance is not within the predetermined range, the sensing device 150-6 may, for example, transmit an error value between this pressing distance and the distance D3 to the processor 110, so that the processor 110 may output a compensation signal to the pressing device 140 according to this error value to adjust the movement accuracy of the pressing device 140. The over-pressing or non-pressing problems of the chips to be tested C1 to C5 are thus prevented.

It should be noted that the reason why the sensing device 150-6 needs to wait until the pressing device 140 moves toward the test sockets 130-1 to 130-5 by the distance D2 before detecting the pressing distance is that before the pressing device 140 moves toward the test sockets 130-1 to 130-5 based on the test signal, the pressing device 140 is located at a topmost position of the automated chip testing device 100 and cannot move upward. Therefore, the pressing device 140 needs to move toward the test sockets 130-1 to 130-5 by the distance D2 before it is conducive to performing the above-mentioned operation of adjusting the movement accuracy.

It should be noted that in the foregoing paragraphs, one sensing device 150-6 is used to detect the pressing distance. If it is needed to enhance the prevention capability for over-pressing or non-pressing problems of the chips to be tested C1 to C5, multiple sensing devices (e.g., pressing devices 150-2 to 150-6) may also be used to detect the distance between the lower surface of the pressing rod 141 and the chips to be tested C1 to C5 (that is, multiple pressing distances). Accordingly, when most of the pressing distances (or any pressing distance) between the multiple pressing distances are not within the predetermined range, the processor 110 may output a compensation signal to the pressing device 140, so that the over-pressing or non-pressing problems of the chips to be tested C1 to C5 may be avoided.

According to the above, the automated chip testing device 100 of the disclosure makes the pressing device 140 move by a fixed distance and detects the pressing distance through the sensing devices 150-1 to 150-6, so as to determine whether an error occurs in the moving distance of the pressing device 140 and further instruct the processor 110 to perform dynamic compensation for the occurring error. In this way, the over-pressing and non-pressing problems of the chips to be tested C1 to C5 may be effectively prevented. It is worth mentioning that the chips to be tested C1 to C5 may have different thicknesses, so the over-pressing and non-pressing problems of the chips to be tested C1 to C5 may occur. The solution provided by the above embodiments may also respond to this situation, so that the chips to be tested C1 to C5 may be prevented from being damaged, and the stability and reliability of testing are thus effectively improved.

In addition to the above-mentioned incorrect startup time of the test program, poor sensing accuracy, and over-pressing and non-pressing problems, warpage problems of the chips to be tested C1 to C5 may also occur frequently during the testing process. Specifically, during the process of the pick-up device 120 placing the chips to be tested C1 to C5 on the test sockets 130-1 to 130-5, warpage problems of the chips to be tested C1 to C5 may be caused due to component wear of the pick-up device 120, foreign objects existing on the test sockets, or unevenness of the chips to be tested C1 to C5. If the chips to be tested C1 to C5 are in a warped state, the protruding portions 1421 to 1425 may damage the chips after pressing.

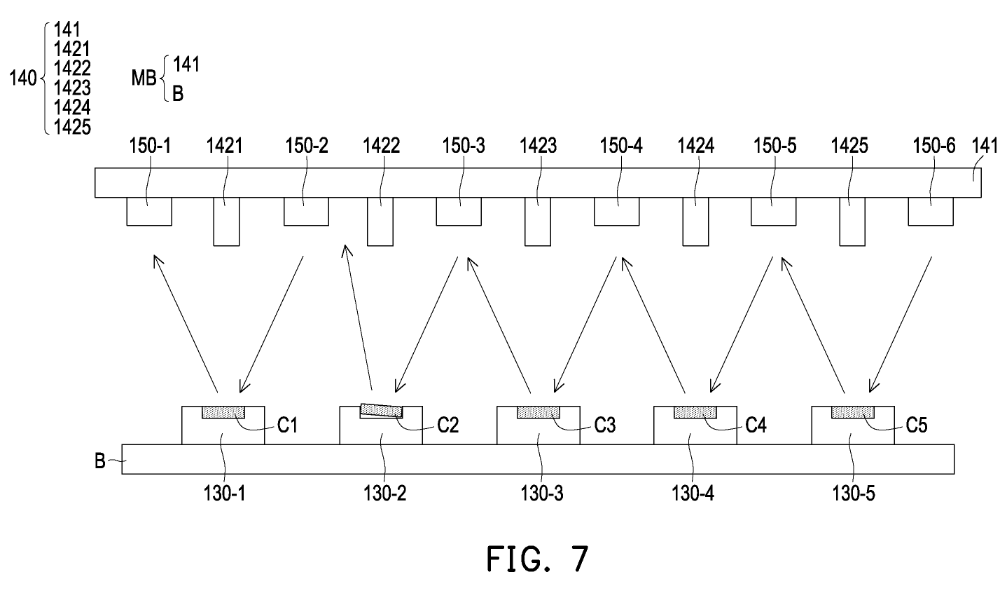

FIG. 7 is a schematic view of management of a warpage issue according to the first embodiment of the disclosure. With reference to FIG. 7, in this embodiment, after the pick-up device 120 places the chips to be tested C1 to C5 on the test sockets 130-1 to 130-5, the sensing devices 150-1 to 150-6 may be used to detect whether the chips to be tested C1 to C5 have warpage problems.

In this embodiment, to detect whether the chip to be tested C1 has a warpage problem, the sensing device 150-2 (also referred to as a first sensing device) with a transmission function may transmit a detection signal (e.g., an optical signal) to a surface of the chip to be tested C1 in the test socket 130-1. Subsequently, the sensing device 150-1 (also referred to as a second sensing device) with a reception function may receive the detection signal reflected from the surface of the chip to be tested C1. Specifically, the sensing device 150-1 determines whether it receives the detection signal within a predetermined range. If yes, it indicates that the chip to be tested C1 does not have a warpage problem. Conversely, if no, it indicates that the chip to be tested C1 has a warpage problem, and the sensing device 150-1 may transmit an alarm signal to the processor 110. The processor 110 may transmit a stop signal to the pressing device 140 based on the alarm signal to stop the operation of the pressing device 140 and temporarily not start the test program to avoid damaging the chip to be tested C1. In addition, the processor 110 may also output an alarm notification based on the alarm signal to instruct the test personnel to resolve the warpage problem.

In another embodiment, to detect whether the chips to be tested C1 to C5 have warpage problems, the sensing devices 150-2 to 150-6 may respectively transmit detection signals (e.g., optical signals) to the surfaces of the chips to be tested C1 to C5 in the test sockets 130-1 to 130-5. Subsequently, the sensing devices 150-1 to 150-5 may respectively receive the detection signals reflected from the surfaces of the chips to be tested C1 to C5.

In this embodiment, the sensing devices 150-1 to 150-5 may determine whether they all receive the detection signals within the predetermined range. As shown in FIG. 5, the chip to be tested C1 and the chips to be tested C3 to C5 are respectively placed flatly on the test socket 130-1 and the test sockets 130-3 to 130-5. Therefore, the detection signals reflected from the surfaces of the chip to be tested C1 and the chips to be tested C3 to C5 may accurately reflect to the predetermined ranges of the sensing device 150-1 and the sensing devices 150-3 to 150-5, respectively.

Conversely, the chip to be tested C2 in FIG. 5 is not placed flatly on the test socket 130-2. Therefore, the detection signal reflected from the surface of the chip to be tested C2 is shifted, so the sensing device 150-2 is unable to receive the detection signal reflected from the surface of the chip to be tested C2 within the predetermined range. Since the sensing device 150-2 does not receive the detection signal reflected from the surface of the chip to be tested C2 within the predetermined range, the sensing device 150-2 may transmit an alarm signal to the processor 110 Accordingly, the processor 110 may transmit a stop signal to the pressing device 140 based on the alarm signal to stop the operation of the pressing device 140 and temporarily not start the test program to avoid damaging the chip to be tested C2. In addition, the processor 110 may also output an alarm notification based on the alarm signal to instruct the test personnel to resolve the warpage problem of the chip to be tested C2.

In addition, after the sensing device 150-1 and the sensing devices 150-3 to 150-5 respectively receive the detection signals reflected from the surfaces of the chip to be tested C1 and the chips to be tested C3 to C5 within the predetermined range, the sensing device 150-1 and the sensing devices 150-3 to 150-5 may further determine whether intensity of the received detection signals is within predetermined intensity. In detail, if the intensity of the received detection signal is within the predetermined intensity, it indicates that the chip to be tested reflecting this detection signal has been placed flatly on the test socket. Conversely, if the intensity of the received detection signal is not within the predetermined intensity (the intensity of the received detection signal is excessively high or excessively low due to different directions of chip warpage), it indicates that this detection signal has been offset (that is, the chip to be tested reflecting this detection signal has a warpage problem), causing part of the detection signal to fall outside the predetermined range. Accordingly, the sensing device that receives a detection signal with intensity not greater than the predetermined intensity may transmit an alarm signal to the processor 110, enabling the processor 110 to output the aforementioned stop signal and alarm notification based on the alarm signal to avoid adverse effects caused by the warpage problems and to further determine whether the chip to be tested is warped based on the intensity of the detection signal within the predetermined range. In this way, detection accuracy is improved, and situations where the test sockets C1 to C5, after long-term use, cannot fully constrain the chips to be tested, resulting in the chips to be tested being within the predetermined range but in a warped state, are prevented from occurring.

It can be understood that if the chips to be tested are in a flat state, the sensing devices 150-3 to 150-5 may have consistent intensity between the transmitted detection signal and the received detection signal. If the chips to be tested is in a warped state, the sensing devices 150-3 to 150-5 may receive detection signals that are excessively high or excessively low during the receiving process. In actual processes, determining whether the chips to be tested are flat according to the detection signal intensity requires a longer determination time for the processor 110. Therefore, determining whether the chips to be tested are flat according to the predetermined range is prioritized.

It should be noted that in this embodiment, the sensing devices 150-2 to 150-5 may be, for example, non-contact sensing devices (or optical sensing devices) that have both transmission and reception functions. That is, the sensing devices 150-2 to 150-5 may serve as both the first sensing device and the second sensing device. The approach of using the sensing devices that have both the transmission and reception functions to detect the warpage problems of the chips to be tested C1 to C5 can effectively save installation costs and space. Additionally, in this embodiment, the sensing device 150-1 disposed on a side of the pressing rod 141 may be, for example, a non-contact sensing device (or an optical sensing device) that only has the reception function, and the sensing device 150-6 disposed on the other side of the pressing rod 141 may be, for example, a non-contact sensing device (or an optical sensing device) that only has the transmission function. Alternatively, the sensing devices 150-1 and 150-6 may also be, for example, non-contact sensing devices (or optical sensing devices) that have both the transmission and reception functions.

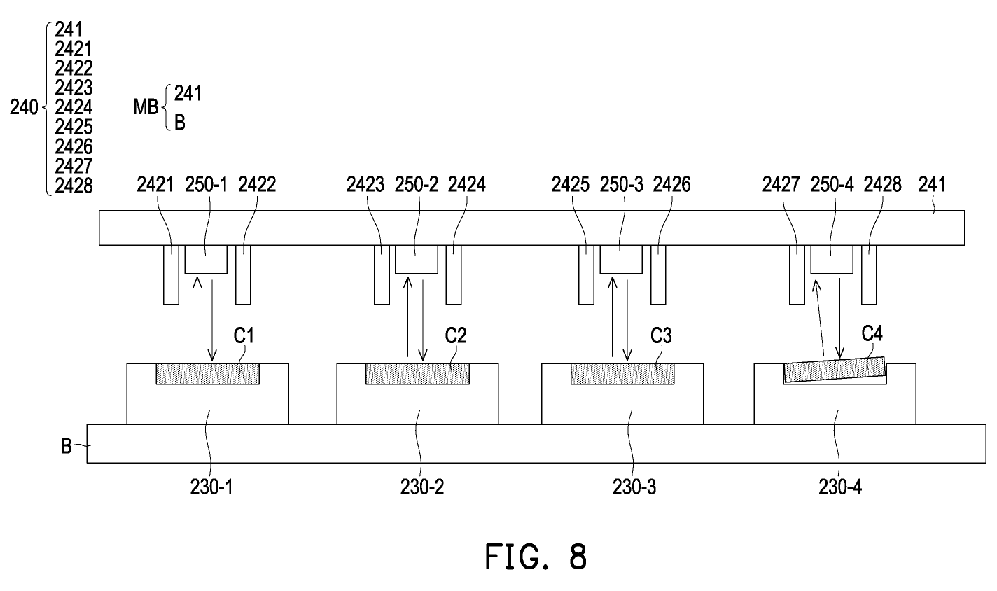

FIG. 8 is a schematic view of test sockets, the chips to be tested, the main body, a pressing device, and sensing devices according to a second embodiment of the disclosure.

With reference to FIG. 8, in this embodiment, the number of test sockets 230-1 to 230-4 is 4, and the number of sensing devices 250-1 to 250-4 is 4. A pressing device 240 includes a pressing rod 241 and protruding portions 2421 to 2428 disposed on the pressing rod 241. The main body MB includes the machine main body B and the pressing rod 241. The test sockets 230-1 to 230-4, the pressing device 240, and the sensing devices 250-1 to 250-4 are located on the main body MB.

The test sockets 230-1 to 230-4 are spaced apart from each other and disposed on the machine main body B. The sensing devices 250-1 to 250-4 are located on the pressing device 240 and are correspondingly disposed with the test sockets 230-1 to 230-4. For instance, the sensing device 250-1 in FIG. 6 is disposed between the protruding portion 2421 and the protruding portion 2422. The sensing device 250-2 is disposed between the protruding portion 2423 and the protruding portion 2424. The sensing device 250-3 is disposed between the protruding portion 2425 and the protruding portion 2426. The sensing device 250-4 is disposed between the protruding portion 2427 and the protruding portion 2428. Since the sensing devices 250-1 to 250-4 are disposed between the protruding portions 2421 to 2428, in this embodiment, a height of the sensing devices 250-1 to 250-4 needs to be lower than a height of the protruding portions 2421 to 2428, so that the pressing of the chips to be tested C1 to C4 by the pressing device 240 can be prevented from being affected.

In this embodiment, the pressing device 240 may move toward the test sockets 230-1 to 230-4 based on the test signal from the processor 110, so as to press the chips to be tested C1 to C4 in the test sockets 230-1 to 230-4 through the protruding portions 2421 to 2428. Further, the sensing devices 250-1 to 250-4 may also respectively detect whether a distance between themselves and the objects to be sensed (e.g., the chips to be tested C1 to C4) satisfies a predetermined condition (for example, reaching a predetermined distance) based on the test signal from the processor 110. When the distance between the sensing devices 250-1 to 250-4 and the chips to be tested C1 to C4 reaches this predetermined distance, the sensing devices 250-1 to 250-4 may instruct the processor 110 to start a test program. Accordingly, the test efficiency and correctness of the chips can be effectively improved.

It is worth mentioning that in the second embodiment of the disclosure, the aforementioned self-detection mechanism, management for over-pressing and non-pressing issues, and management for warpage issues may also be adopted to optimize the overall testing process.

Specifically, after the pick-up device 120 places the chips to be tested C1 to C4 respectively on the test sockets 230-1 to 230-4, the sensing devices 250-1 to 250-4 may respectively be used to detect whether the corresponding chips to be tested C1 to C4 in the test sockets 230-1 to 230-4 have warpage issues. In this embodiment, the sensing devices 250-1 to 250-4 may be, for example, non-contact sensing devices (or optical sensing devices) that have both transmitting and receiving functions.

The implementation details of using the second embodiment of the disclosure to manage the warpage issues of chips to be tested are described in the following paragraphs. First, the sensing devices 250-1 to 250-4 may respectively transmit detection signals (e.g., optical signals) to the surfaces of the chips to be tested C1 to C4 in the test sockets 230-1 to 230-4. Next, the sensing devices 250-1 to 250-4 may respectively receive the detection signals reflected from the surfaces of the chips to be tested C1 to C4. Specifically, as shown in FIG. 6, the chip to be tested C4 has a warpage issue. The detection signal reflected from the surface of the chip to be tested C4 is shifted, so the sensing device 250-4 is unable to receive the detection signal reflected from the surface of the chip to be tested C4 within a predetermined range. Accordingly, the sensing device 250-4 may transmit an alarm signal to the processor 110. The processor 110 may transmit a stop signal to the pressing device 240 based on the alarm signal to stop the operation of the pressing device 240, so that the chip to be tested C4 is prevented from being damaged. In addition, the processor 110 may also issue an alarm notification based on the alarm signal, so as to instruct the test personnel to resolve the warpage issue of the chip to be tested C4.

After the test personnel resolve the warpage issue of the chip to be tested C4, the aforementioned self-detection mechanism and/or management for over-pressing and non-pressing issues may be further executed, so that the stability and correctness of testing are effectively improved.

In addition, regarding the implementation details of using the second embodiment of the disclosure to execute the self-detection mechanism and/or management for over-pressing and non-pressing issues, reference may be made to the aforementioned first embodiment or analogized from the aforementioned first embodiment, so description thereof is not repeated herein.

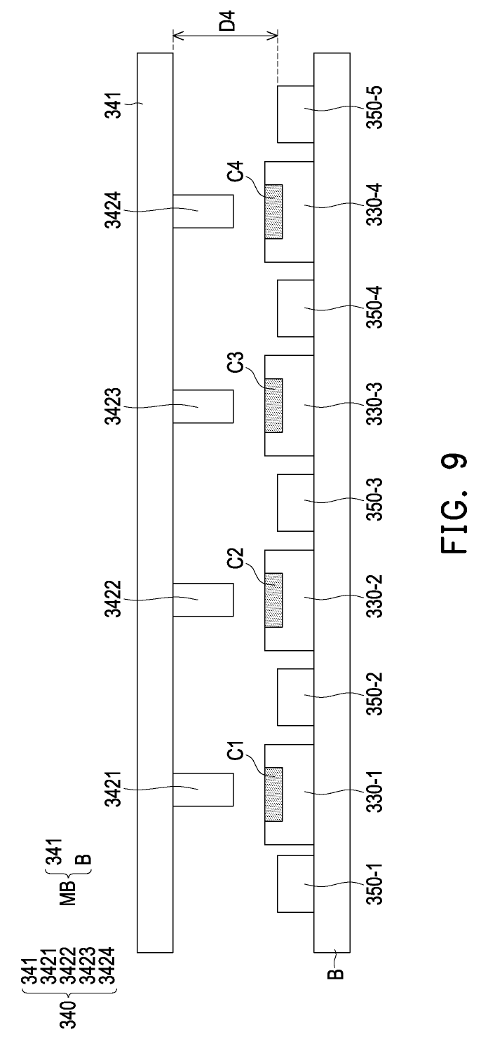

FIG. 9 is a schematic view of test sockets, the chips to be tested, the main body, a pressing device, and sensing devices according to a third embodiment of the disclosure.

With reference to FIG. 9, in this embodiment, the number of test sockets 330-1 to 330-4 is 4, and the number of sensing devices 350-1 to 350-5 is 5. A pressing device 340 includes a pressing rod 341 and protruding portions 3421 to 3424 disposed on the pressing rod 341. The main body MB includes the machine main body B and the pressing rod 341. The test sockets 330-1 to 330-4, the pressing device 340, and the sensing devices 350-1 to 350-5 are located on the main body MB.

The test sockets 330-1 to 330-4 are spaced apart from each other and disposed on the machine main body B. The sensing devices 350-1 to 350-5 are located on a surface of the main body MB facing the pressing device 340 (also referred to as a first surface). In this embodiment, the sensing devices 350-1 to 350-5 and the test sockets 330-1 to 330-4 are disposed on the machine main body B in an alternating manner. For instance, the sensing devices 350-2 to 350-4 in FIG. 7 are respectively disposed between the test sockets 330-1 to 330-4, the sensing device 350-1 is disposed on the left side of the test socket 340-1, and the sensing device 350-5 is disposed on the right side of the test socket 330-4. In this embodiment, a height of the test sockets 330-1 to 330-4 needs to be higher than a height of the sensing devices 350-1 to 350-5, so that the pressing of the chips to be tested C1 to C4 by the pressing device 440 can be prevented from being affected.

In this embodiment, the pressing device 340 may move toward the test sockets 330-1 to 330-4 based on a test signal from the processor 110, so as to press the chips to be tested C1 to C4 in the test sockets 330-1 to 330-4 through the protruding portions 3421 to 3424 respectively. Further, the sensing devices 350-1 to 350-5 may determine whether a distance between themselves and an object to be sensed (e.g., the pressing rod 341) is a distance D4 based on the test signal. When the distance between the sensing devices 350-1 to 350-5 and the pressing rod 341 is the distance D4, the sensing devices 350-1 to 350-5 may instruct the processor 110 to start a test program. Accordingly, the test efficiency and correctness of the chips can be effectively improved.

It is worth mentioning that in the third embodiment of the disclosure, the aforementioned self-detection mechanism and/or management for over-pressing and non-pressing issues may also be adopted to optimize the overall testing process. Regarding the implementation details of using the third embodiment of the disclosure to execute the self-detection mechanism and/or management for over-pressing and non-pressing issues, reference may be made to the aforementioned first embodiment or analogized from the aforementioned first embodiment, so description thereof is not repeated herein.

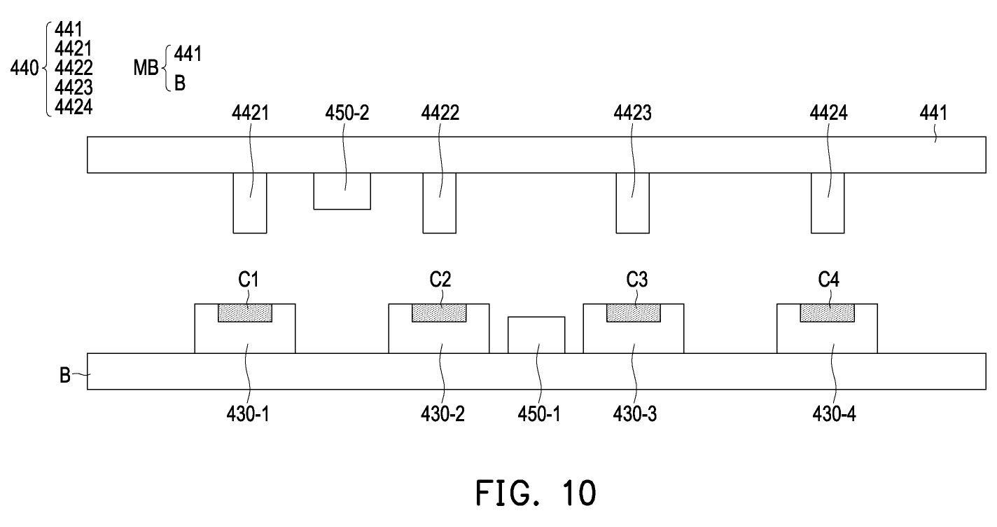

FIG. 10 is a schematic view of test sockets, the chips to be tested, the main body, a pressing device, and sensing devices according to a fourth embodiment of the disclosure.

With reference to FIG. 10, in this embodiment, the number of test sockets 430-1 to 430-4 is 4, and the number of sensing devices 450-1 to 450-2 is 2. A pressing device 440 includes a pressing rod 441 and protruding portions 4421 to 4424 disposed on the pressing rod 441. The main body MB includes the machine main body B and the pressing rod 441. The test sockets 430-1 to 430-4 are spaced apart from each other and disposed on the machine main body B. In this embodiment, the sensing device 450-1 is disposed between the test socket 430-2 and the test socket 430-3, and the sensing device 450-2 is disposed between the protruding portion 4421 and the protruding portion 4422. The sensing device 450-1 is located on a surface of the main body MB facing the pressing device 440 (also referred to as a first surface). In this embodiment, heights of the protruding portions 4421 to 4424 and the test sockets 430-1 to 430-4 need to be higher than a height of the sensing devices 450-1 and 450-2, so that the pressing of the chips to be tested C1 to C4 by the pressing device 440 can be prevented from being affected.

In this embodiment, the pressing device 440 may move toward the test sockets 430-1 to 430-4 based on a test signal from the processor 110, so as to press the chips to be tested C1 to C4 in the test sockets 430-1 to 430-4 through the protruding portions 4421 to 4424 respectively. Further, the sensing device 450-1 and/or the sensing device 450-2 may determine whether a distance between themselves and an object to be sensed satisfies a predetermined condition based on the test signal. For instance, the sensing device 450-1 may determine whether the distance between itself and the pressing rod 441 reaches a predetermined distance based on the test signal, and if yes, the sensing device 450-1 may determine that the predetermined condition is satisfied. For instance, the sensing device 450-2 may determine whether the distance between itself and the machine main body B (or the test sockets 430-1 and 430-2 or the chips to be tested C1 and C2) reaches a predetermined distance based on the test signal, and if yes, the sensing device 450-2 may determine that the predetermined condition is satisfied. When the predetermined condition is satisfied, the sensing device 450-1 (or the sensing device 450-2) may instruct the processor 110 to start a test program, so that the test program is executed at the most appropriate time, and the testing efficiency and correctness of the chips are thus effectively improved.

It is worth mentioning that in the fourth embodiment of the disclosure, the aforementioned self-detection mechanism and management for over-pressing and non-pressing issues may also be adopted to optimize the overall testing process.

Regarding the implementation details of using the fourth embodiment of the disclosure to execute the management for over-pressing and non-pressing issues, reference may be made to the aforementioned first embodiment and third embodiment or analogized from the aforementioned first embodiment and third embodiment, so description thereof is not repeated herein. The implementation details of using the fourth embodiment of the disclosure to execute the self-detection mechanism are described in the following paragraphs.

In this embodiment, before the pressing device 440 moves toward the test sockets 430-1 to 430-4 based on a detection signal, the sensing device 450-2 may be used to detect a distance between itself and the first surface (also referred to as a first distance), and the sensing device 450-1 may be used to detect a distance between itself and the pressing rod 441 (also referred to as a second distance).

The sensing device 450-1 and the sensing device 450-2 may respectively transmit the first distance and the second distance to the processor 110. Accordingly, the processor 110 may determine whether a predetermined threshold is exceeded according to the first distance and the second distance. For instance, the processor 110 may calculate an error value between the first distance and the second distance and determine whether this error value exceeds the predetermined threshold. If the predetermined threshold is not exceeded, the pressing device 440 may continue to move toward the test sockets 430-1 to 430-4 to press the chips to be tested C1 to C4, and the sensing devices 450-1 and 450-2 may continue to detect the distance between themselves and the objects to be sensed. In contrast, if the predetermined threshold is exceeded, the processor 110 may transmit a stop signal to the pressing device 440 to instruct the pressing device 440 to stop moving. In addition, the processor 110 may also issue an abnormality notification to instruct the test personnel to perform maintenance on the sensing devices 450-1 and 450-2, so that the accuracy of the sensing devices 450-1 and 450-2 is ensured, and the correctness of testing is effectively improved.

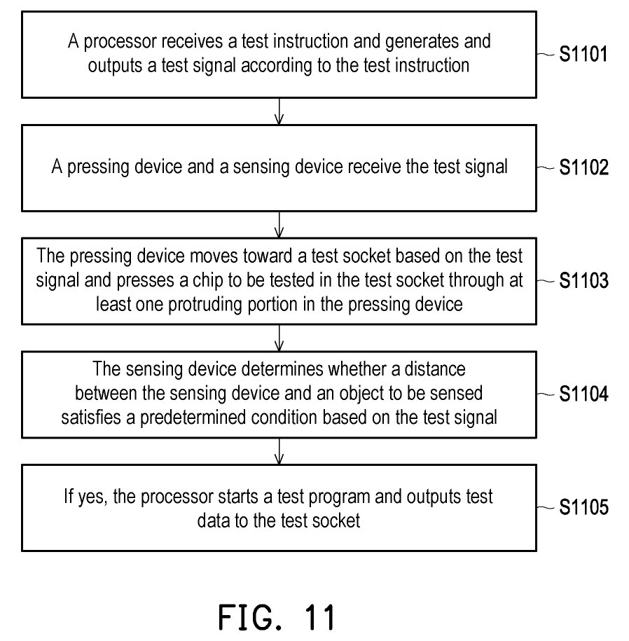

FIG. 11 is a flow chart of an automated chip testing method according to an embodiment of the disclosure. Referring to FIG. 11, in step S1101, a processor receives a test instruction and generates and outputs a test signal according to the test instruction. In step S1102, a pressing device and a sensing device receive the test signal. In step S1103, the pressing device moves toward a test socket based on the test signal and presses a chip to be tested in the test socket through at least one protruding portion in the pressing device. In step S1104, the sensing device determines whether a distance between the sensing device and an object to be sensed satisfies a predetermined condition based on the test signal. In step S1105, if yes, the processor starts a test program and outputs test data to the test socket.

However, each step in FIG. 11 has been described in detail in the foregoing paragraphs, so description thereof is not repeated herein. It should be noted that each step in FIG. 11 may be implemented as a plurality of program codes or circuits, which is not particularly limited by the disclosure. In addition, the method of FIG. 11 may be used in combination with the above-described embodiments or may be used solely, which is not particularly limited by the disclosure.

In view of the above, in the automated chip testing device and automated chip testing method provided by the embodiments of the disclosure, testing efficiency and testing correctness may be improved, and the chips to be tested are prevented from being damaged.

Finally, it is worth noting that the foregoing embodiments are merely described to illustrate the technical means of the disclosure and should not be construed as limitations of the disclosure. Even though the foregoing embodiments are referenced to provide detailed description of the disclosure, people having ordinary skill in the art should understand that various modifications and variations can be made to the technical means in the disclosed embodiments, or equivalent replacements may be made for part or all of the technical features; nevertheless, it is intended that the modifications, variations, and replacements shall not make the nature of the technical means to depart from the scope of the technical means of the embodiments of the disclosure.

What is claimed is:

1. An automated chip testing device, comprising:
a main body;
a processor configured to receive a test instruction and generate and output a test signal according to the test instruction;
at least one test socket located on the main body, coupled to the processor, and configured to be placed with a chip to be tested;
a pressing device located on the main body, coupled to the processor, and comprising a pressing rod and at least one protruding portion disposed on the pressing rod, wherein the pressing device is configured to receive the test signal, and based on the test signal, the pressing device moves toward the at least one test socket and presses the chip to be tested in the at least one test socket through the at least one protruding portion; and
at least one sensing device located on the main body and coupled to the processor, wherein the at least one sensing device is configured to receive the test signal, and based on the test signal, determine whether a distance between the at least one sensing device and an object to be sensed satisfies a predetermined condition,
if yes, the processor starts a test program and outputs test data to the at least one test socket.

2. The automated chip testing device according to claim 1, wherein the at least one sensing device is located on a first surface of the main body, and the first surface is a surface facing the pressing device.

3. The automated chip testing device according to claim 1, wherein the at least one sensing device is located on the pressing device.

4. The automated chip testing device according to claim 3, wherein the at least one protruding portion further comprises a first protruding portion and a second protruding portion, the at least one sensing device is located between the first protruding portion and the second protruding portion, and the first protruding portion and the second protruding portion are higher than the at least one sensing device.

5. The automated chip testing device according to claim 3, wherein the at least one sensing device further comprises a first sensing device and a second sensing device,
the first sensing device is configured to emit a detection signal to a surface of the chip to be tested in the at least one test socket,
the second sensing device is configured to receive the detection signal reflected from the surface of the chip to be tested,
if the second sensing device does not receive the detection signal within a predetermined range, the second sensing device transmits an alarm signal to the processor, and
the processor transmits a stop signal to the pressing device based on the alarm signal and outputs an alarm notification.

6. The automated chip testing device according to claim 1, wherein after the pressing device moves toward the at least one test socket by a predetermined distance, the at least one sensing device is further configured to detect a pressing distance and determine whether the pressing distance is within a predetermined distance range, and
if not within the predetermined distance range, the processor outputs a compensation signal to the pressing device, and the pressing device adjusts a pressing-down distance according to the compensation signal.

7. The automated chip testing device according to claim 6, wherein the pressing distance is a distance between the pressing rod and the first surface or the chip to be tested.

8. The automated chip testing device according to claim 1, wherein the at least one sensing device further comprises a third sensing device and a fourth sensing device,
the third sensing device is configured to detect a first distance,
the fourth sensing device is configured to detect a second distance,
the processor is further configured to determine whether a predetermined threshold is exceeded according to the first distance and the second distance, and
if yes, the processor transmits a stop signal to the pressing device and outputs an abnormality notification.

9. The automated chip testing device according to claim 8, wherein the first distance is a distance between the third sensing device and the first surface, and
the second distance is a distance between the fourth sensing device and the pressing rod.

10. An automated chip testing method, comprising:
receiving a test instruction and generating and outputting a test signal by a processor according to the test instruction;
receiving the test signal by a pressing device and a sensing device;
moving the pressing device toward a test socket based on the test signal and pressing a chip to be tested in the test socket through at least one protruding portion in the pressing device;
determining whether a distance between the sensing device and an object to be sensed satisfies a predetermined condition by the sensing device based on the test signal; and
if yes, starting a test program and outputting test data to the test socket by the processor.
